(19) United States
(12) Patent Application Publication
(10) Pub. No.: US 2014/0368980 A1
(43) Pub. Date: Dec. 18, 2014

(54) Technical Support and Remote Functionality for a Wearable Computing System

(71) Applicants: Sharvil Nanavati, Dundas (CA); Casey Kwok Ching Ho, San Jose, CA (US)

(72) Inventors: Sharvil Nanavati, Dundas (CA); Casey Kwok Ching Ho, San Jose, CA (US)

(73) Assignee: GOOGLE INC., Mountain View, CA (US)

(21) Appl. No.: 13/367,736

(22) Filed: Feb. 7, 2012

(51) Int. Cl. H05K 7/00

(52) U.S. Cl. 361/679.03

(57) ABSTRACT

Methods and systems for providing technical support for a wearable computing system are described. The wearable computing system may receive a command from a user requesting assistance with operation of the wearable computing system and may initiate a technical support session to request the assistance. The wearable computing system may be connected to a technical support associate through a technical support server over a network and may provide through the technical support server a camera feed of a camera coupled to the wearable computing system, information associated with sensors coupled to the wearable computing system, and access for operating the wearable computing system to the technical support associate. The wearable computing system may also provide an audio communication channel between the user and the technical support associate through a microphone coupled to the wearable computing system. The wearable computing system may receive and execute commands through the technical support session.

### BACKGROUND

Technical support or tech support refers to a range of services by which enterprises provide assistance to users of technology products, e.g., computers. In general, technical support services attempt to help the user solve specific problems with a product, and possibly even provide training, customization, or other support services. Technical support may be delivered over the telephone, online by e-mail, or using a website or a tool where users can log a call/incident.

In some examples, technical support may offer remote computer support, which includes a method for troubleshooting software related problems via remote desktop connections, in which programs may be run on a server and displayed locally to a user. For instance, a technician may use software that allows the technician to access and control the user's desktop computer via the Internet. With the user's permission, the technician can take control of the user's desktop computer (e.g., including control of a mouse and keyboard coupled to the desktop computer), transfer various diagnostic and repair applications to the user's desktop computer, run scans, install programs, etc.

### SUMMARY

The present application discloses systems and methods for technical support for a wearable computing system. In one aspect, a method is described. The method may comprise receiving, at a wearable computing device, a command to request assistance with operation of the wearable computing device. The wearable computing device may include a head-mounted display (HMD). The method may also comprise initiating, by the wearable computing device, a technical support session to request the assistance with operation of the wearable computing device. The method may further comprise providing to a first source associated with the technical support session, by the wearable computing device, access for operating the wearable computing device, a view of a content displayed on the HMD, and information output by one or more sensors coupled to the wearable computing device. The method may also comprise receiving, at the wearable computing device, a first command from the first source based on one or more of: (i) the view of the content displayed on the HMD, and (ii) the information output by the one or more sensors coupled to the wearable computing device. The method may further comprise providing an audio communication channel, through a microphone coupled to the wearable computing device. The method may also comprise receiving, at the wearable computing device, a second command from a second source based at least in part on communication by way of the audio communication channel. The method may further comprise executing, by the wearable computing device, one or more of the first command and the second command.

In another aspect, a computer readable memory having stored thereon instructions executable by a computing device to cause the computing device to perform functions is described. The functions may comprise initiating, by a wearable computing device, a technical support session to request assistance with operation of the wearable computing device. The wearable computing device may include a head-mounted display (HMD). The functions may also comprise providing to a source associated with the technical support session, by the wearable computing device, access for operating the wearable computing device, a camera feed of a field of view of a camera coupled to the wearable computing device in a forward facing configuration, a view of a content displayed on the HMD, and information output by one or more sensors coupled to the wearable computing device. The functions may further comprise receiving, at the wearable computing device, a command from the source based on one or more of: (i) the camera feed, (ii) the view of the content displayed on the HMD, and (iii) the information output by the one or more sensors coupled to the wearable computing device. The functions may also comprise executing, by the wearable computing device, the command.

In still another aspect, a system is described. The system may comprise a wearable computing device including a head-mounted display (HMD). The system may also comprise a camera coupled to the wearable computing device in a forward facing configuration, a microphone coupled to the wearable computing device, and one or more sensors coupled to the wearable computing device. The system may further comprise a processor in communication with the wearable computing device, the camera, the microphone, and the one or more sensors. The processor may be configured to initiate a technical support session to request assistance with operation of the wearable computing device. The processor may also be configured to provide access for operating the wearable computing device to a first source associated with the technical support session. The processor may further be configured to provide to the first source a camera feed of a field of view of the camera, a view of a content displayed on the HMD, and information associated with a condition of the wearable computing device including information output by the one or more sensors. The processor may also be configured to receive from the first source a first command based on one or more of: (i) the camera feed, (ii) the view of the content displayed on the HMD, and (iii) the information associated with the condition of the wearable computing device. The processor may further be configured to provide an audio communication channel, through the microphone. The processor may also be configured to receive a second command from a second source based at least in part on communication by way of the audio communication channel. The processor may further be configured to execute one or more of the first command and the second command.

The foregoing summary is illustrative only and is not intended to be in any way limiting. In addition to the illustrative aspects, embodiments, and features described above, further aspects, embodiments, and features will become apparent by reference to the figures and the following detailed description.

### BRIEF DESCRIPTION OF THE FIGURES

FIG. 1 is an example wearable computing and head-mounted display system, in accordance with an example embodiment.

FIG. 2A illustrates a front view of an example wearable computing system including a head-mounted display (HMD) in an example eyeglasses embodiment.

FIG. 2B illustrates a side view of the HMD in the example eyeglasses embodiment.

FIG. 3 illustrates an example technical support system for a wearable computing system, in accordance with an example embodiment.

FIG. 4 illustrates an example technical support system for a wearable computing system including the HMD, in accordance with an example embodiment.

FIG. 5 is a flow chart of an example method to provide technical support for the example wearable computing system.

FIG. 6 is a functional block diagram illustrating an example computing device used in a computing system that is arranged in accordance with at least some embodiments described herein.

FIG. 7 is a schematic illustrating a conceptual partial view of an example computer program product that includes a computer program for executing a computer process on a computing device, arranged according to at least some embodiments presented herein.

### DETAILED DESCRIPTION

The following detailed description describes various features and functions of the disclosed systems and methods with reference to the accompanying figures. In the figures, similar symbols identify similar components, unless context dictates otherwise. The illustrative system and method embodiments described herein are not meant to be limiting. It may be readily understood that certain aspects of the disclosed systems and methods can be arranged and combined in a wide variety of different configurations, all of which are contemplated herein.

This disclosure may disclose systems and methods for providing technical support for a wearable computing system. The wearable computing system may include a head mounted display (HMD). The wearable computing system may receive a command requesting assistance with operating the wearable computing system and may initiate a technical support session to request the assistance. The wearable computing system may be connected to a technical support server through a network and may provide to a technical support associate by way of the technical support server a view of a content displayed on the HMD, a camera feed of a camera coupled to the wearable computing system, and information associated with sensors coupled to the wearable computing system. The wearable computing system may also provide to the technical support associate, through the network and the technical support server, access for operating the wearable computing system. The wearable computing system may further provide an audio communication channel between a user and the technical support associate through a microphone coupled to the wearable computing system. The wearable computing system may receive and execute commands during on the technical support session.

In one example, a wearable computing system may include a head mounted display (HMD), and a camera to capture a field of view of a user of the wearable computing system. A user may require assistance performing an action, executing a function on the wearable computing system, repairing the wearable computing system, or other tasks. The wearable computing system may be operated to send a request to a technical support server. The request may indicate a type of assistance requested. The request may further include information associated with sensors of the wearable computing system so as to provide additional information to give context of the wearable computing system and/or context of the assistance requested.

As one example, a user may operate the wearable computing system to initiate a technical support session to request assistance with operating the wearable computing system. A technical support associate may connect to the wearable computing system and observe what the user may be doing on the wearable computing system (e.g., receive a view of the display screen of the wearable computing system through screen sharing), execute commands on the user's behalf (e.g., allowing commands to be sent over a network to the wearable computing system that may be executed by the wearable computing system), and communicate directly with the user (e.g., through use of a microphone and display available on the wearable computing system to initiate a communication channel between the user and the associate). Thus, the user may use all abilities and sensors of the wearable computing system to obtain the assistance with operation of the wearable computing system.

As another specific example, the request may include information such as a camera feed of the wearable computing system that may provide to a technical support server a video (either recorded or in real-time) that may be provided from a camera coupled to the wearable computing system. In an example in which the wearable computing system takes the form of a head mounted device (e.g., eyeglasses) and the camera may be mounted to the glasses to record video from a field of view of the head mounted device, the video provided to the technical support server (and also to a technical support associate or personnel) may include a video from the field of view of the user. In this example, the user may be running an application on the wearable computing system in which information may be displayed on the HMD that corresponds to an ambient environment of the wearable computing system. A technical support associate may receive the camera feed as well as the displayed information so as to determine how to advise the user. Thus, in examples, the technical support associate may receive information associated with the ambient environment in which the wearable computing system may be operated so that the technical support associate can see what the user may be seeing, hear what the user may be hearing, and provide an enhanced technical support experience to the user.

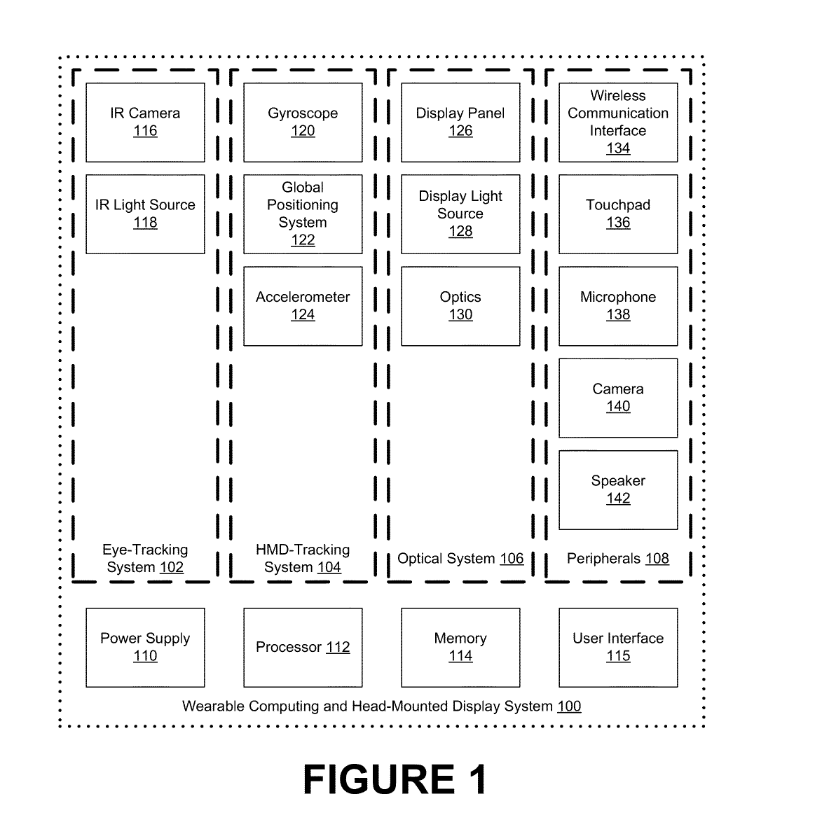

Referring now to the figures, FIG. 1 is a block diagram of an example wearable computing and head-mounted display (HMD) system 100 that may include several different components and subsystems. Components coupled to or included in the system 100 may include an eye-tracking system 102, a HMD-tracking system 104, an optical system 106, peripherals 108, a power supply 110, a processor 112, a memory 114, and a user interface 115. Components of the system 100 may be configured to work in an interconnected fashion with each other and/or with other components coupled to respective systems. For example, the power supply 110 may provide power to all the components of the system 100. The processor 112 may receive information from and may control the eye tracking system 102, the HMD-tracking system 104, the optical system 106, and peripherals 108. The processor 112 may be configured to execute program instructions stored in the memory 114 to generate a display of images on the user interface 115.

The eye-tracking system 102 may include hardware such as an infrared camera 116 and at least one infrared light source 118. The infrared camera 116 may be utilized by the eye-tracking system 102 to capture images of an eye of the wearer. The images may include either video images or still images or both. The images obtained by the infrared camera 116 regarding the eye of the wearer may help determine where the wearer may be looking within a field of view of the HMD included in the system 100, for instance, by ascertaining a location of the eye pupil of the wearer. The infrared camera 116 may include a visible light camera with sensing capabilities in the infrared wavelengths.

The infrared light source 118 may include one or more infrared light-emitting diodes or infrared laser diodes that may illuminate a viewing location, i.e. an eye of the wearer. Thus, one or both eyes of a wearer of the system 100 may be illuminated by the infrared light source 118. The infrared light source 118 may be positioned along an optical axis common to the infrared camera, and/or the infrared light source 118 may be positioned elsewhere. The infrared light source 118 may illuminate the viewing location continuously or may be turned on at discrete times.

The HMD-tracking system 104 may include a gyroscope 120, a global positioning system (GPS) module 122, and an accelerometer 124. The HMD-tracking system 104 may be configured to provide information associated with a position and an orientation of the HMD to the processor 112. The gyroscope 120 may include a microelectromechanical system (MEMS) gyroscope or a fiber optic gyroscope as examples. The gyroscope 120 may be configured to provide orientation information to the processor 112. The GPS module 122 may include a receiver that obtains clock and other signals from GPS satellites and may be configured to provide real-time location information to the processor 112. The HMD-tracking system 104 may further include an accelerometer 124 configured to provide motion input data to the processor 112.

The optical system 106 may include components configured to provide images to a viewing location, i.e. an eye of the wearer. The components may include a display panel 126, a display light source 128, and optics 130. These components may be optically and/or electrically-coupled to one another and may be configured to provide viewable images at the eye of the wearer. One or two optical systems 106 may be provided in the system 100. In other words, the HMD wearer may view images in one or both eyes, as provided by one or more optical systems 106. Also, the optical system(s) 106 may include an opaque display and/or a see-through display coupled to the display panel 126, which may allow a view of the real-world environment while providing superimposed virtual images. The infrared camera 116 coupled to the eye tracking system 102 may be integrated into the optical system 106.

Additionally, the system 100 may include or be coupled to peripherals 108, such as a wireless communication interface 134, a touchpad 136, a microphone 138, a camera 140, and a speaker 142. Wireless communication interface 134 may use 3G cellular communication, such as CDMA, EVDO, GSM/GPRS, or 4G cellular communication, such as WiMAX or LTE. Alternatively, wireless communication interface 134 may communicate with a wireless local area network (WLAN), for example, using WiFi. In some examples, wireless communication interface 134 may communicate directly with a device, for example, using an infrared link, Bluetooth, near field communication, or ZigBee.

The power supply 110 may provide power to various components in the system 100 and may include, for example, a rechargeable lithium-ion battery. Various other power supply materials and types known in the art are possible.

The processor 112 may execute instructions stored in a non-transitory computer readable medium, such as the memory 114, to control functions of the system 100. Thus, the processor 112 in combination with instructions stored in the memory 114 may function as a controller of system 100. For example, the processor 112 may control the wireless communication interface 134 and various other components of the system 100. In other examples, the processor 112 may include a plurality of computing devices that may serve to control individual components or subsystems of the system 100. Analysis of the images obtained by the infrared camera 116 may be performed by the processor 112 in conjunction with the memory 114.

In addition to instructions that may be executed by the processor 112, the memory 114 may store data that may include a set of calibrated wearer eye pupil positions and a collection of past eye pupil positions. Thus, the memory 114 may function as a database of information related to gaze direction and location. Calibrated wearer eye pupil positions may include, for instance, information regarding extents or range of an eye pupil movement (right/left and upwards/downwards), and relative position of eyes of the wearer with respect to the HMD.

The system 100 may further include the user interface 115 for providing information to the wearer or receiving input from the wearer. The user interface 115 may be associated with, for example, displayed images, a touchpad, a keypad, buttons, a microphone, and/or other peripheral input devices. The processor 112 may control functions of the system 100 based on input received through the user interface 115. For example, the processor 112 may utilize user input from the user interface 115 to control how the system 100 may display images within a field of view or may determine what images the system 100 may display.

Although FIG. 1 shows various components of the system 100 (i.e., wireless communication interface 134, processor 112, memory 114, infrared camera 116, display panel 126, GPS module 122, and user interface 115) as being integrated into the system 100, one or more of the described functions or components of the system 100 may be divided up into additional functional or physical components, or combined into fewer functional or physical components. For example, the infrared camera 116 may be mounted on the wearer separate from the system 100. Thus, the system 100 may be part of a wearable computing device in the form of separate devices that can be worn on or carried by the wearer. Separate components that make up the wearable computing device may be communicatively coupled together in either a wired or wireless fashion. In some further examples, additional functional and/or physical components may be added to the examples illustrated by FIG. 1. In other examples, the system 100 may be included within other systems.

The system 100 may be configured as, for example, eyeglasses, goggles, a helmet, a hat, a visor, a headband, or in some other form that can be supported on or from a head of the wearer. The system 100 may be further configured to display images to both eyes of the wearer. Alternatively, the system 100 may display images to only one eye, either a left eye or a right eye.

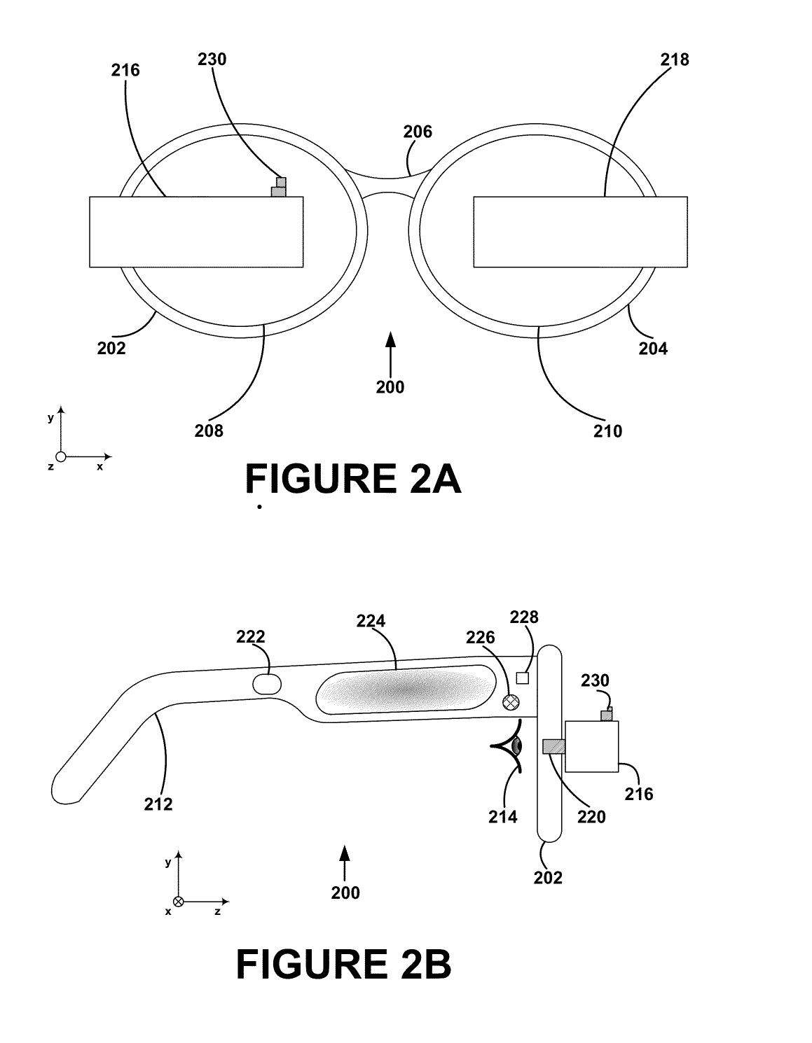

FIG. 2A illustrates a front view of an example wearable computing system including a head-mounted display (HMD) 200 in an example eyeglasses embodiment. FIG. 2B presents a side view of the HMD 200 in FIG. 2A. FIGS. 2A and 2B will be described together. Although this example embodiment is provided in an eyeglasses format, it will be understood that wearable systems and HMDs may take other forms, such as hats, goggles, masks, headbands and helmets. The HMD 200 may include lens frames 202 and 204, a center frame support 206, lens elements 208 and 210, and extending side-arm 212 that may be affixed to lens frame 202. There may be another extending side arm affixed to the lens frame 204 but is not shown. The center frame support 206 and side-arm 212 may be configured to secure the HMD 200 to a head of a wearer via a nose and an ear of the wearer. Each of the frame elements 202, 204, and 206 and the extending side-arm 212 may be formed of a solid structure of plastic or metal, or may be formed of a hollow structure of similar material so as to allow wiring and component interconnects to be internally routed through the HMD 200. Lens elements 208 and 210 may be at least partially transparent so as to allow the wearer to look through lens elements. In particular, a right eye 214 of the wearer may look through right lens 210. Optical systems 216 and 218 may be positioned in front of lenses 208 and 210, respectively. The optical systems 216 and 218 may be attached to the HMD 200 using support mounts such as 220 shown for the right optical system 216. Furthermore, the optical systems 216 and 218 may be integrated partially or completely into lens elements 208 and 210, respectively.

Although FIG. 2A illustrates an optical system for each eye, the HMD 200 may include an optical system for only one eye (e.g., right eye 214). The wearer of the HMD 200 may simultaneously observe from optical systems 216 and 218 a real-world image with an overlaid displayed image. The HMD 200 may include various elements such as a processor 222, a touchpad 224, a microphone 226, and a button 228. The processor 222 may use data from, among other sources, various sensors and cameras to determine a displayed image that may be displayed to the wearer. The HMD 200 may also include a forward facing camera 230 that may be integrated into the optical systems 216. Location of the forward facing camera 230 is for illustration only. The forward facing camera 230 may be positioned in different locations and may be separate or attached to the HMD 200. More than one forward facing camera may be used in some examples. Those skilled in the art would understand that other user input devices, user output devices, wireless communication devices, sensors, and cameras may be reasonably included in such a wearable computing system.

The wearable computing and head-mounted display system 100 including, for example, the HMD 200, may be configured to enable a user to observe surroundings of the user and also view a displayed image on a display of the optical systems 216 and 218. The user of the system 100 may request assistance to operate the system 100, in some examples, and may request the assistance from a technical support associate that may be located close to and have direct communication with the user or may be located in a remote location and communicate with the user through a technical support server over a network.

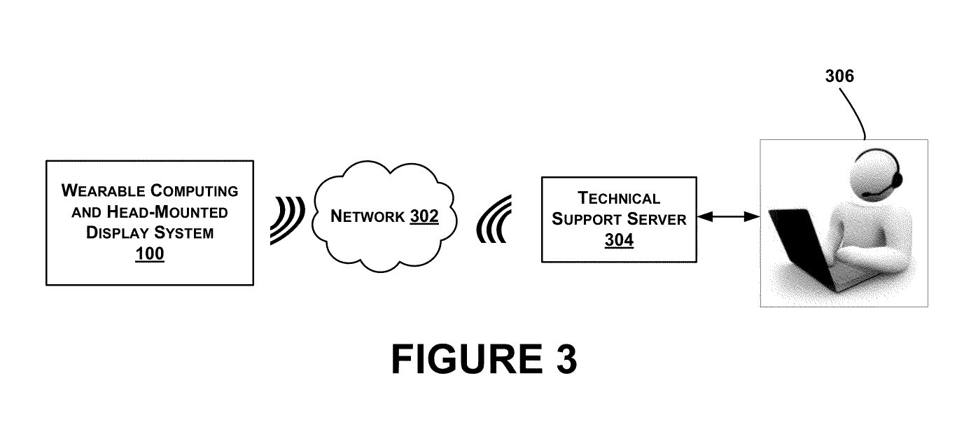

FIG. 3 illustrates an example technical support system for a wearable computing system, e.g., system 100, in accordance with an example embodiment. The system 100 may include the HMD 200 of FIG. 2, for example. A user of the system 100 may request assistance with operation of the system 100 and, accordingly, the system 100 may be configured to initiate a technical support session to request the assistance. The system 100 may be configured to be in networked communication through a network 302 with a technical support server 304. A technical support associate 306 may also have access to the technical support server 304 and may communicate with the system 100 through the technical support server 304 over the network 302, which may be wired or wireless. In other examples, the system 100 may be configured to communicate directly with the technical support server 304 or technical support associate 306 through point-to-point links, for example.

In examples, through the technical support server 304 and over the network 302, the system 100 may be configured to provide to the technical support associate 306 a view of a content displayed on an HMD coupled to the system 100, information associated with sensors coupled to the system 100, and a camera feed of a forward facing camera coupled to the system 100. The system 100 may further be configured to provide an audio communication channel through a microphone coupled to the system 100 between the user of the system 100 and the technical support associate 306. The system 100 may also be configured to provide, through the technical support server 304, access for operating the system 100 to the technical support associate 306.

Therefore, the technical support associate 306 may be able to observe what the user may be performing with or on the system 100, to see what the user may be seeing, and to obtain information associated with a condition of the system 100 through the information associated with the sensors coupled to the system 100, for example. The technical support associate 306 may also be able to communicate with the user through the audio communication channel. As a result of having access to information provided by the system 100, through the network 302 and the technical support server 304, and communication with the user, the technical support associate 306 may be able to advise the user to take actions or may send commands through the technical support server 304 over the network 302 to the system 100.

In an example, the technical support server 304 may have stored thereon instructions for operation of the system 100 that may be accessed by the user over the network 302. The technical support server 304 may also initiate sending to the system 100 commands and diagnostic routines that may determine a condition of the system 100, for example.

In one example, the user may require assistance with operation of the system 100 including software components and/or hardware components coupled to the system 100, and the technical support associate 306 may, through communication by way of the audio communication channel, advise the user with specific steps on how to operate the system 100 as desired by the user. The system 100 may receive commands from the technical support server 304, possibly initiated by the technical support associate 306, over the network 302 that may be executed at the system 100 to configure or cause the system 100 to operate as desired by the user.

In another example, the system 100 may malfunction and the user may require assistance with repairing the system 100. Certain actions may be performed on the system 100 based, for example, on communication between the technical support associate 306 and the user. The actions or commands received at the system 100 may cause the system 100 to be repaired.

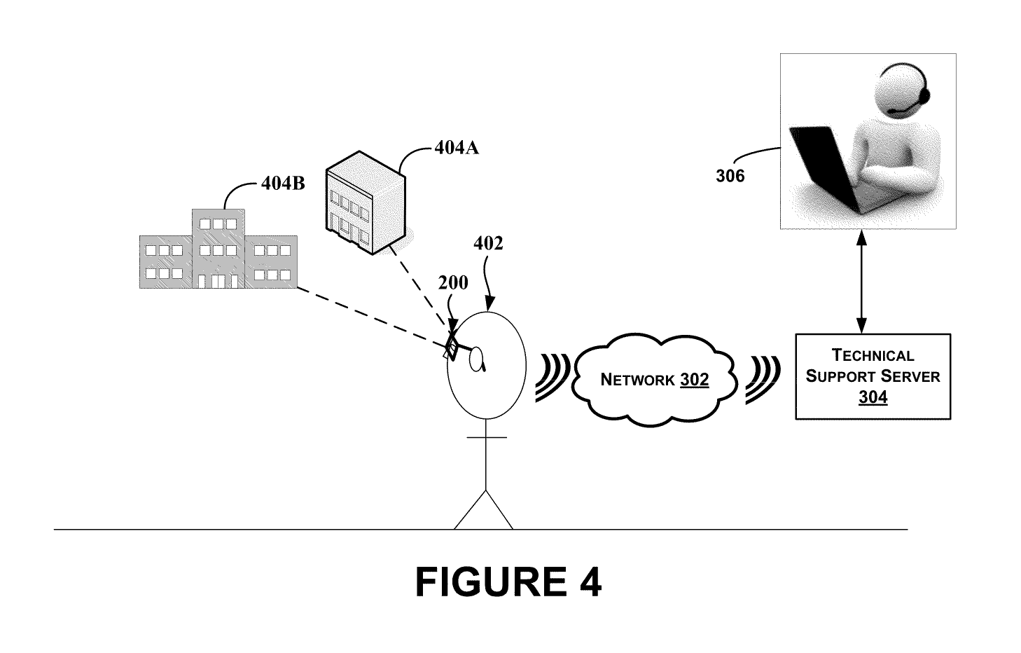

FIG. 4 is an example technical support system for a wearable computing system including the HMD 200, in accordance with an example embodiment. FIG. 4 shows a specific example of a type of assistance that may be requested for illustration only. Other examples are possible. FIG. 4 shows a user 402 wearing the HMD 200 and in communication over the network 302 with the technical support server 304. The technical support associate 306 may also have access to the technical support server 304 either directly or through wired or wireless network. The technical support associate 306 may thus communicate with the HMD 200 through the technical support server 304 over the network 302.

In an example, the user may be looking at buildings such as buildings 404A-B and the HMD 200 may be configured to recognize a building, through a forward facing camera coupled to the HMD 200, and to generate a display of information associated with the building. The user 402 may be looking at building 404A, for example, and may observe that the HMD 200 outputs information associated with building 404B instead. The HMD 200 may be configured to receive a command to request assistance to identify a cause of this apparent malfunction and the HMD 200 may accordingly be configured to initiate a technical support session.

The HMD 200 may be configured to provide to the technical support associate 306, over the network 302 and through the technical support server 304, a camera feed of the forward facing camera coupled to the HMD 200. The HMD 200 may also be configured to provide a view of a content displayed on the HMD 200. Also, the HMD 200 may be configured to provide, through the network 302 and the technical support server 304, a communication channel between the user 402 and the technical support associate 306 by way of a microphone coupled to the HMD 200.

There may be several causes for the HMD 200 to generate a display of inaccurate information. For illustration purposes only, the reason may include the forward facing camera being out of calibration. Therefore, the user 402 may be looking at the building 404A but a field of view of the forward facing camera coupled to the HMD 200 may include building 404B instead because of the forward facing camera calibration problem, as an example. The technical support associate 306 may be able to recognize such malfunction from the information provided over the network 302 and through technical support server 304 by the HMD 200 and may accordingly ask the user 402 to perform certain actions on the HMD 200, for example. The HMD 200 may also receive commands over the network 302 through the technical support server 304 to repair the malfunction by calibrating the forward facing camera.

The example in FIG. 4 is for illustration only. Other sensors or functions of the HMD 200 may be configured by the technical support associate 306 as well. In other examples, the HMD 200 may not be malfunctioning but the user 402 may require assistance in using capabilities of the HMD 200 to perform a certain task. The HMD 200 may receive a visual instruction on a display of the HMD 200 or an auditory instruction through communication by way of the communication channel relating to performance of the task, for example. Other examples are also possible.

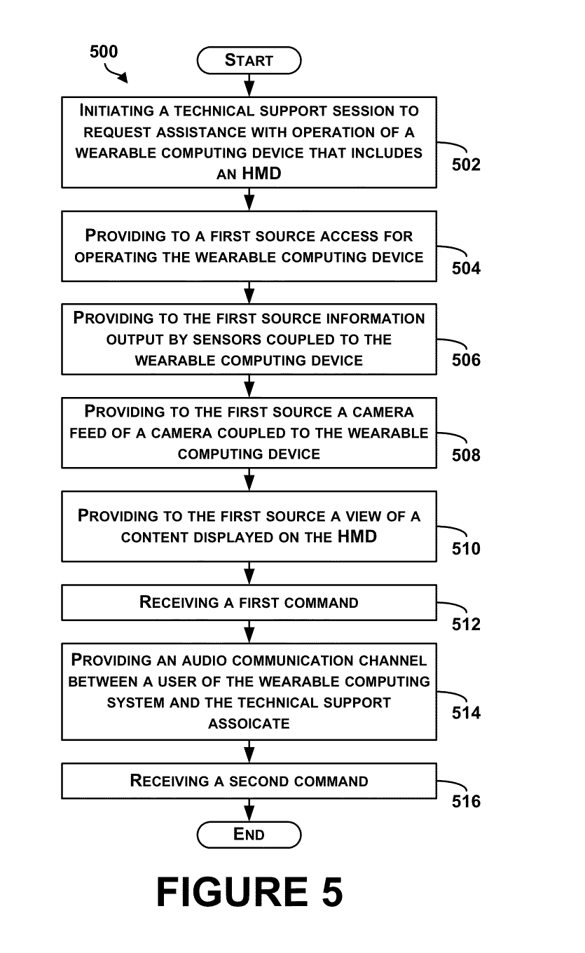

FIG. 5 is a flow chart of an example method to provide technical support for a wearable computing system, in accordance with at least some embodiments of the present disclosure. Method 500 described in FIG. 5 may, for example, be used by systems described in FIGS. 1-4.

The method 500 may include one or more operations, functions, or actions as illustrated by one or more of blocks 502-516. Although the blocks are illustrated in a sequential order, these blocks may in some instances be performed in parallel, and/or in a different order than those described herein. Also, the various blocks may be combined into fewer blocks, divided into additional blocks, and/or removed based upon the desired implementation

In addition, for the method 500 and other processes and methods disclosed herein, the flowchart shows functionality and operation of one possible implementation of present embodiments. In this regard, each block may represent a module, a segment, or a portion of program code, which includes one or more instructions executable by a processor for implementing specific logical functions or steps in the process. The program code may be stored on any type of computer readable medium or memory, for example, such as a storage device including a disk or hard drive. The computer readable medium may include a non-transitory computer readable medium, for example, such as computer-readable media that stores data for short periods of time like register memory, processor cache and Random Access Memory (RAM). The computer readable medium may also include non-transitory media or memory, such as secondary or persistent long term storage, like read only memory (ROM), optical or magnetic disks, compact-disc read only memory (CD-ROM), for example. The computer readable media may also be any other volatile or non-volatile storage systems. The computer readable medium may be considered a computer readable storage medium, a tangible storage device, or other article of manufacture, for example.

In addition, for the method 500 and other processes and methods disclosed herein, each block in FIG. 5 may represent circuitry that is wired to perform the specific logical functions in the process.

A user of a wearable computing system may be in an ambient environment and may request assistance in operation of the wearable computing system. The user may, for example, request help with software and/or hardware components of the wearable computing system. In another example, the wearable computing system may malfunction and the user may request help with repairing the wearable computing system. In still other examples, the wearable computing system may initiate a request for assistance or calibration based on outputs of sensors of the wearable computing system.

At block 502, the method 500 includes initiating a technical support session to request assistance with operation of a wearable computing system that includes an HMD. The wearable computing system may be configured to receive a command to request the assistance with operation of the wearable computing system. In an example, a technical support server may be operable to receive the request through the network from the wearable computing system and process the request to start the technical support session. The technical support session may comprise communication over a network—wired or wireless—between the wearable computing system and the technical support server. A technical support associate may have access to the technical support server.

At block 504, the method 500 includes providing to a first source access for operating the wearable computing system. After the technical support session may be initiated, the wearable computing system may be configured to provide access to operate the wearable computing system through the technical support server over the network, for example. The technical support server may, in this example, be considered the first source. The technical support server may be configured to send commands to the wearable computing system over the network, for example. In an example, the commands may be provided to the technical support server by the technical support associate. Thus, the technical support associate may, in the example, send commands through the technical support server and over the network to be executed at the wearable computing system. In the example, the technical support associate may be considered the first source.

In one example, the wearable computing system may be configured to provide full access to operate the wearable computing system through the technical support server and may provide all information output by and stored on the wearable computing system. In another example, the wearable computing system may be configured to provide partial access to operate the wearable computing system through the technical support server and may provide limited access to information output by and stored on the wearable computing system with a limited or partial ability to command the wearable computing system through the technical support server.

At block 506, the method 500 includes providing to the first source information output by sensors coupled to the wearable computing system. The wearable computing system may be configured to provide to the technical support server, through the network, information output by the sensors. The information output by the sensors may provide to the technical support associate information associated with a condition of the wearable computing system, for example. Several types of sensors may be coupled to the wearable computing system such as an accelerometer, a gyroscope, a magnetometer, eye-tracking sensors, temperature sensors, etc. By having access, through the technical support server, to information output by such sensors may allow the technical support associate to diagnose a malfunction of the wearable computing system, for example.

In an example, information output by temperature sensors coupled to the wearable computing system (e.g., to measure ambient temperature, processor temperature, and/or average overall temperature of the system) can be sent to the technical support associate. Temperature information may indicate, for example, if the system or components of the system are currently within expected operating temperatures or not. The temperature information may also indicate a cause of a malfunction of the system. For example, a display may not be rendering graphics correctly possibly because the system may be operating outdoors in cold weather and an ambient temperature may be lower than a specified operating temperature of the display. The technical support associate may be able to diagnose such a problem through temperature information, for example.

The wearable computing system may be configured to also provide information indicative of battery condition of a battery powering the wearable computing system and memory usage of a memory coupled to the wearable computing system to the technical support associate through the technical support server.

Further, the information output by the sensors coupled to the wearable computing system may provide information associated with attributes of an ambient environment in which the wearable computing system may be operated such as geographic location (e.g., through a GPS module/antenna coupled to the wearable computing system), and time, for example. The user may choose whether to allow geographic location information be provided or not as a privacy setting.

At block 508, the method 500 includes providing to the first source a camera feed of a camera coupled to the wearable computing system. A forward facing camera may be coupled to the wearable computing system and may provide a camera feed of a field of view of the wearable computing system to the wearable computing system, which may provide the camera feed to the technical support server, over the network. The camera feed may consequently be accessed at the server by the technical support associate. The technical support associate may accordingly be able to determine whether the forward facing camera may be functioning properly or not, for example. The technical support associate may also be able to see what the user may be seeing. The camera feed may be recorded or may be a real-time video feed.

At block 510, the method 500 includes providing to the first source a view of a content displayed on the HMD. The wearable computing system may provide through a screen sharing software application, for example, the view of the content displayed on the HMD. The technical support associate may have access to the view of the content display on the HMD by having access to the technical support server, for example. In this example, the technical support associate may observe interaction of the user with the wearable computing system.

In an example, the forward facing camera may allow the wearable computing system to generate a display of an augmented reality. Augmented reality generally may refer to a real-time view of a real-world environment that may be augmented with an additional content. The wearable computing system may be configured to generate the real-time view of the environment obtained through the forward facing camera, either by allowing the user to directly view the environment or by allowing the user to indirectly view the environment by generating and displaying a real-time representation of the environment to be viewed by the user.

Further, the additional content may include, for example, a user-interface through which the user may interact with the wearable computing system. The wearable computing system may be configured to overlay the view of the environment with the user-interface, such that the user may see the view of the environment and the user-interface at the same time.

By having access to the view of the content displayed on the HMD, the technical support associate may observe the augmented reality displayed on the HMD comprising the user-interface and the real-world environment as described above and may accordingly determine whether software operating the wearable computing system and components coupled to the wearable computing system may be functioning properly or not, for example.

At block 512, the method 500 includes receiving a first command. Based on having access to the information associated with the condition of the wearable computing system including information output by the sensors coupled to the wearable computing system, the camera feed of the field of view of the user, and the view of the content displayed on the HMD, the technical support associate may initiate sending a first command to the technical support server, for example, and the wearable computing system may subsequently receive the first command from the technical support server over the network. The first command may include initiating a repair or calibration routine for a sensor, for instance. In another example, the first command may cause a visual instruction to be displayed on the HMD for the user related to how to operate the wearable computing system to achieve a function desired by the user. In yet another example, the technical support associate may, by having access through the technical support server to the user-interface display on the HMD, select an item on the user-interface and the wearable computing system may receive the selection through the technical support server and may execute a command corresponding to the item selected. Other possible commands are possible. The wearable computing system may receive a series of commands that may cause the wearable computing system to function properly or to function as desired by the user.

At block 514, the method 500 includes providing an audio communication channel between a user of the wearable computing system and the technical support associate. Through a microphone that may be coupled to the wearable computing system, the wearable computing system may be configured to establish an audio communication channel/link between the user and the technical support associate through the network and technical support server, for example. In this example, the technical support associate may hear what the user may be hearing and may instruct the user to perform certain actions on the wearable computing system. As an example, the technical support associate may determine that a possible cause for a given malfunction may be that the forward facing camera may require calibration to function properly. The technical support associate may, for instance, instruct the user to look in a certain direction to cause a known object to be included in the field of the view of the forward facing camera and observe functions of the wearable computing system and may accordingly send, through the technical support server, a given command to the wearable computing system to repair the given malfunction. The technical support associate may instruct the user to perform other functions.

At block 516, the method 500 includes receiving a second command. Based, at least in part on communication by way of the audio communication channel, the wearable computing system may receive a second command. The second command may, for example, result from selecting an item from a menu of the user-interface through a touchscreen or a touchpad coupled to the wearable computing system and the wearable computing system may execute the second command accordingly. In this example, components coupled to the wearable computing system such as the touchscreen or touchpad may be considered as a second source of commands.

Examples used to describe the method 500 are for illustration only. Technical support in general can used for multiple purposes including, for example, configuring the wearable computing system in a certain manner, accomplishing a certain task on or with the wearable computing system by instructing a user, and repairing components of the wearable computing system. Other purposes are also possible.

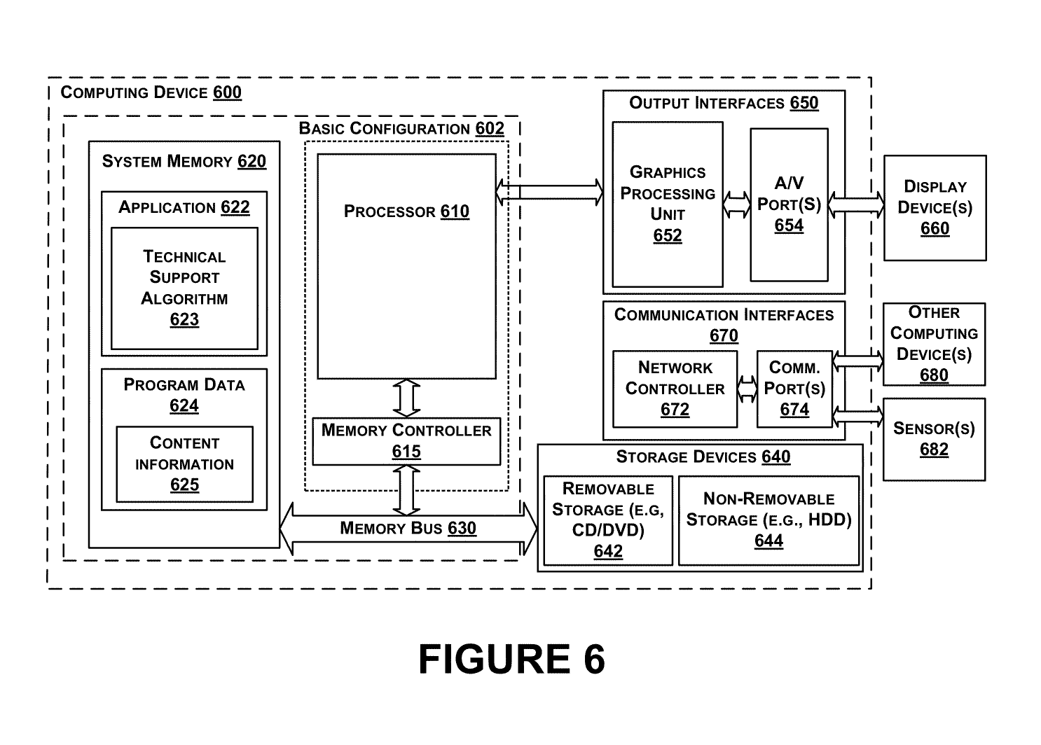

FIG. 6 is a functional block diagram illustrating an example computing device 600 used in a computing system that is arranged in accordance with at least some embodiments described herein. The computing device may be a personal computer, mobile device, cellular phone, video game system, or global positioning system, and may be implemented as a client device, a server, a system, a combination thereof, or as a portion of components described in FIGS. 1, 2, 3, 4, and 6. In a basic configuration 602, computing device 600 may include one or more processors 610 and system memory 620. A memory bus 630 can be used for communicating between the processor 610 and the system memory 620. Depending on the desired configuration, processor 610 can be of any type including but not limited to a microprocessor (IP), a microcontroller (LIC), a digital signal processor (DSP), or any combination thereof. A memory controller 615 can also be used with the processor 610, or in some implementations, the memory controller 615 can be an internal part of the processor 610.

Depending on the desired configuration, the system memory 620 can be of any type including but not limited to volatile memory (such as RAM), non-volatile memory (such as ROM, flash memory, etc.) or any combination thereof. System memory 620 may include one or more applications 622, and program data 624. Application 622 may include technical support algorithm 623 that is arranged to provide inputs to the electronic circuits, in accordance with the present disclosure. Program Data 624 may include content information 625 that could be directed to any number of types of data. In some example embodiments, application 622 can be arranged to operate with program data 624 on an operating system.

Computing device 600 can have additional features or functionality, and additional interfaces to facilitate communications between the basic configuration 602 and any devices and interfaces. For example, data storage devices 640 can be provided including removable storage devices 642, non-removable storage devices 644, or a combination thereof. Examples of removable storage and non-removable storage devices include magnetic disk devices such as flexible disk drives and hard-disk drives (HDD), optical disk drives such as compact disk (CD) drives or digital versatile disk (DVD) drives, solid state drives (SSD), and tape drives to name a few. Computer storage media can include volatile and nonvolatile, non-transitory, removable and non-removable media implemented in any method or technology for storage of information, such as computer readable instructions, data structures, program modules, or other data.

System memory 620 and storage devices 640 are examples of computer storage media. Computer storage media includes, but is not limited to, RAM, ROM, EEPROM, flash memory or other memory technology, CD-ROM, digital versatile disks (DVD) or other optical storage, magnetic cassettes, magnetic tape, magnetic disk storage or other magnetic storage devices, or any other medium which can be used to store the desired information and which can be accessed by computing device 600. Any such computer storage media can be part of device 600.

Computing device 600 can also include output interfaces 650 that may include a graphics processing unit 652, which can be configured to communicate to various external devices such as display devices 660 or speakers via one or more A/V ports 654 or a communication interface 670. The communication interface 670 may include a network controller 672, which can be arranged to facilitate communications with one or more other computing devices 680 and one or more sensors 682 over a network communication via one or more communication ports 674. The one or more sensors 682 are shown external to the computing device 600, but may also be internal to the device. The communication connection is one example of a communication media. Communication media may be embodied by computer readable instructions, data structures, program modules, or other data in a modulated data signal, such as a carrier wave or other transport mechanism, and includes any information delivery media. A modulated data signal can be a signal that has one or more of its characteristics set or changed in such a manner as to encode information in the signal. By way of example, and not limitation, communication media can include wired media such as a wired network or direct-wired connection, and wireless media such as acoustic, radio frequency (RF), infrared (IR) and other wireless media.

Computing device 600 can be implemented as a portion of a small-form factor portable (or mobile) electronic device such as a cell phone, a personal data assistant (PDA), a personal media player device, a wireless web-watch device, a personal headset device, an application specific device, or a hybrid device that include any of the above functions. Computing device 600 can also be implemented as a personal computer including both laptop computer and non-laptop computer configurations.

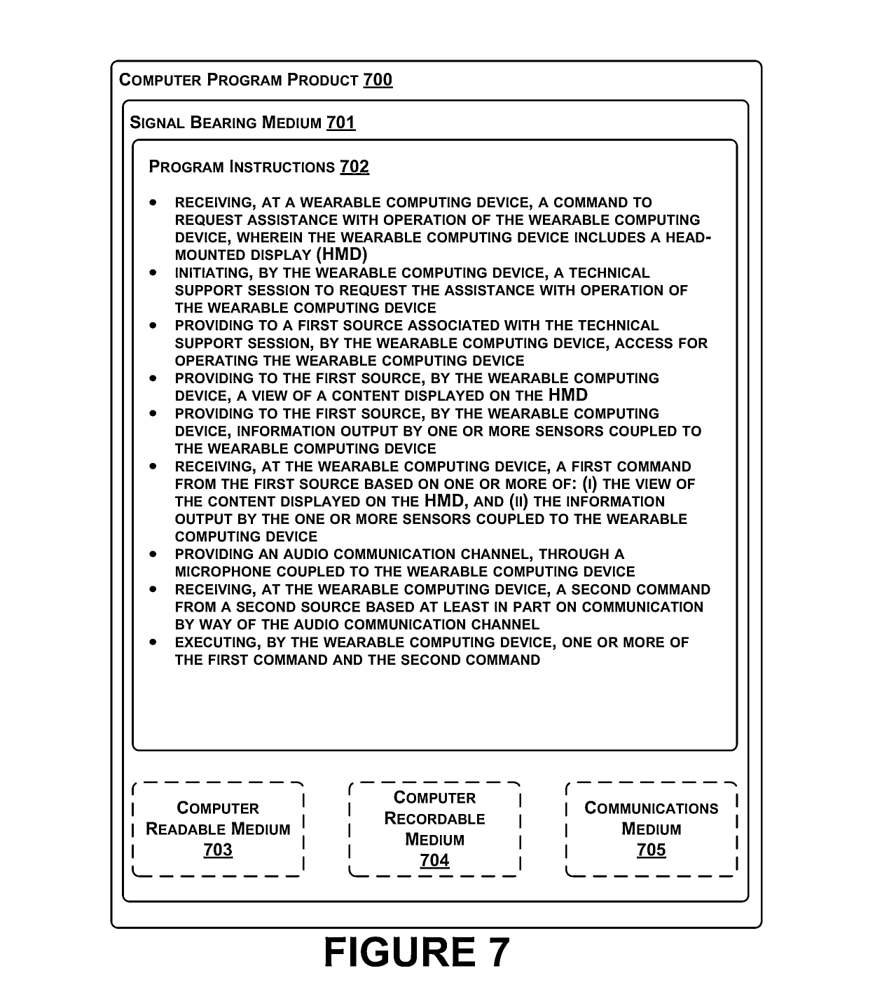

In some embodiments, the disclosed methods may be implemented as computer program instructions encoded on a computer-readable storage media in a machine-readable format, or on other non-transitory media or articles of manufacture. FIG. 7 is a schematic illustrating a conceptual partial view of an example computer program product 700 that includes a computer program for executing a computer process on a computing device, arranged according to at least some embodiments presented herein. In one embodiment, the example computer program product 700 is provided using a signal bearing medium 701. The signal bearing medium 701 may include one or more program instructions 702 that, when executed by one or more processors may provide functionality or portions of the functionality described above with respect to FIGS. 1-6. Thus, for example, referring to the embodiments shown in FIG. 5, one or more features of blocks 502-516 may be undertaken by one or more instructions associated with the signal bearing medium 701. In addition, the program instructions 702 in FIG. 7 describe example instructions as well.

In some examples, the signal bearing medium 701 may encompass a computer-readable medium 703, such as, but not limited to, a hard disk drive, a Compact Disc (CD), a Digital Video Disk (DVD), a digital tape, memory, etc. In some implementations, the signal bearing medium 701 may encompass a computer recordable medium 704, such as, but not limited to, memory, read/write (R/W) CDs, R/W DVDs, etc. In some implementations, the signal bearing medium 701 may encompass a communications medium 705, such as, but not limited to, a digital and/or an analog communication medium (e.g., a fiber optic cable, a waveguide, a wired communications link, a wireless communication link, etc.). Thus, for example, the signal bearing medium 701 may be conveyed by a wireless form of the communications medium 705 (e.g., a wireless communications medium conforming to the IEEE 802.11 standard or other transmission protocol).

The one or more programming instructions 702 may be, for example, computer executable and/or logic implemented instructions. In some examples, a computing device such as the computing device 600 of FIG. 6 may be configured to provide various operations, functions, or actions in response to the programming instructions 702 conveyed to the computing device 600 by one or more of the computer readable medium 703, the computer recordable medium 704, and/or the communications medium 705. It should be understood that arrangements described herein are for purposes of example only. As such, those skilled in the art will appreciate that other arrangements and other elements (e.g. machines, interfaces, functions, orders, and groupings of functions, etc.) can be used instead, and some elements may be omitted altogether according to the desired results. Further, many of the elements that are described are functional entities that may be implemented as discrete or distributed components or in conjunction with other components, in any suitable combination and location.

While various aspects and embodiments have been disclosed herein, other aspects and embodiments will be apparent to those skilled in the art. The various aspects and embodiments disclosed herein are for purposes of illustration and are not intended to be limiting, with the true scope being indicated by the following claims, along with the full scope of equivalents to which such claims are entitled. It is also to be understood that the terminology used herein is for the purpose of describing particular embodiments only, and is not intended to be limiting.

1. A method comprising:
receiving, by a camera coupled to a head-mountable display (HMD) of a wearable computing device, a camera feed indicative of a wearer-view through a field of view of the HMD, wherein the HMD is at least partially transparent, and wherein the wearer-view includes an environment of the HMD;
in response to receiving the camera feed, generating, by the wearable computing device, a view of a content displayed on the HMD, wherein the content overlays the environment of the wearable computing device in the wearer-view, and wherein the content is indicative of a malfunction related to operation of a sensor of a plurality of sensors coupled to the wearable computing device, the plurality of sensors including the camera;
in response to the content being indicative of the malfunction related to operation of the sensor, initiating, via a wireless communication interface coupled to the wearable computing device, a technical support session to request assistance with operation of the wearable computing device;
providing to a first source associated with the technical support session, by the wearable computing device, access for operating the wearable computing device;
providing to the first source, by the wearable computing device, the camera feed;
providing to the first source, by the wearable computing device, the view of the content indicative of the malfunction;
providing to the first source, by the wearable computing device, information output by one or more sensors of the plurality of sensors that are different from the camera;
receiving, at the wearable computing device, a first command from the first source based on: (i) the view of the content displayed on the HMD, (ii) the information output by the one or more sensors, and (iii) the camera feed;
providing an audio communication channel, through a microphone coupled to the wearable computing device;
receiving, at the wearable computing device, a second command from a second source based at least in part on communication by way of the audio communication channel; and
based on one or more of the first command and the second command, the wearable computing device adjusting one or more parameters associated with the sensor so as to remove at least a portion of the malfunction.

2. The method of claim 1, wherein the information output by the one or more sensors provide information associated with an ambient environment in which the wearable computing device is operated.

3. (canceled)

4. The method of claim 1, wherein the camera feed provides a recorded video associated with the wearer-view through the field of view of the HMD.

5. The method of claim 1, wherein the camera feed provides a real-time video of the wearer-view through the field of view of the HMD.

6. The method of claim 1, wherein the malfunction is related to operation of the camera, and wherein adjusting the one or more parameters associated with the sensor based on the one or more of the first command and the second command comprises calibrating the camera.

7. The method of claim 1, wherein the information output by the one or more sensors that are different from the camera indicates that the malfunction is related to operation of at least one sensor of the one or more sensors.

8. (canceled)

9. The method of claim 7, wherein adjusting the one or more parameters associated with the sensor based on the one or more of the first command and the second command comprises calibrating the at least one sensor of the one or more sensors.

10. A computer readable memory having stored thereon instructions executable by a wearable computing device to cause the wearable computing device to perform functions comprising:
receiving, by a camera coupled to a head-mountable display (HMD) of the wearable computing device in a forward-facing configuration, a camera feed indicative of a wearer-view through a field of view of the HMD, wherein the HMD is at least partially transparent, and wherein the wearer-view includes an environment of the HMD;
in response to receiving the camera feed, generating, by the wearable computing device, a view of a content displayed on the HMD, wherein the content overlays the environment of the wearable computing device in the wearer-view, and wherein the content is indicative of a malfunction related to operation of a sensor of a plurality of sensors coupled to the wearable computing device, the plurality of sensors including the camera;
in response to the content being indicative of the malfunction related to operation of the sensor, initiating, via a wireless communication interface coupled to the wearable computing device, a technical support session to request assistance with operation of the wearable computing device.
providing to a source associated with the technical support session, by the wearable computing device, access for operating the wearable computing device;
providing to the source, by the wearable computing device, the camera feed;
providing to the source, by the wearable computing device, the view of the content indicative of the malfunction;
providing to the source, by the wearable computing device, information output by one or more sensors of the plurality of sensors that are different from the camera;
receiving, at the wearable computing device, a command from the source based on: (i) the camera feed, (ii) the view of the content displayed on the HMD, and (iii) the information output by the one or more sensors; and
based on the command, the wearable computing device adjusting one or more parameters associated with the sensor so as to remove at least a portion of the malfunction.

11. The computer readable memory of claim 10, wherein the instructions are further executable by the wearable computing device to cause the wearable computing device to perform functions comprising:
providing an audio communication channel, through a microphone coupled to the wearable computing device;
receiving, at the wearable computing device, a given command from a given source associated with the technical support session based at least in part on communication by way of the audio communication channel; and
executing, by the wearable computing device, the given command.

12. The computer readable memory of claim 10, wherein the information output by the one or more sensors that are different from the camera indicates that the malfunction is related to operation of at least one sensor of the one or more sensors.

13. (canceled)

14. The computer readable memory of claim 10, wherein the function of adjusting the one or more parameters associated with the sensor based on the command comprises calibrating the at least one of the one or more sensors.

15. The computer readable memory of claim 10, wherein the camera feed provides a recorded video associated with the wearer-view through the field of view of the HMD.

16. The computer readable memory of claim 10, wherein the camera feed provides a real-time video of the wearer-view through the field of view of the HMD.

17. The computer readable memory of claim 10, wherein the information output by the one or more sensors provide information associated with one or more attributes of a current environment in which the wearable computing device is operated.

18. A system comprising:
a wearable computing device including a head-mountable display (HMD) that is at least partially transparent;
a plurality of sensors coupled to the wearable computing device, wherein the plurality of sensors include a camera coupled to the HMD in a forward facing configuration and further include one or more sensors different from the camera;
a microphone coupled to the wearable computing device; and
a processor in communication with the wearable computing device, the microphone, and the plurality of sensors, wherein the processor is configured to:
receive, via the camera, a camera feed indicative of a wearer-view through a field of view of the HMD, wherein the wearer-view includes an environment of the HMD;
in response to receiving the camera feed, generate a view of a content displayed on the HMD, wherein the content overlays the environment of the wearable computing device in the wearer-view, and wherein the content is indicative of a malfunction related to operation of a sensor of the plurality of sensors coupled to the wearable computing device;
in response to the content being indicative of the malfunction related to operation of the sensor, initiate a technical support session to request assistance with operation of the wearable computing device;
provide access for operating the wearable computing device to a first source associated with the technical support session;
provide to the first source the camera feed;
provide to the first source the view of the content indicative of the malfunction;
provide to the first source information associated with a condition of the wearable computing device including information output by the one or more sensors that are different from the camera;
receive from the first source a first command based on: (i) the camera feed, (ii) the view of the content displayed on the HMD, and (iii) the information associated with the condition of the wearable computing device;
provide an audio communication channel, through the microphone;
receive a second command from a second source based at least in part on communication by way of the audio communication channel; and
based on one or more of the first command and the second command, adjust one or more parameters associated with the sensor so as to remove at least a portion of the malfunction.

19. The system of claim 18, wherein the wearable computing device is in a form of a pair of eyeglasses.

20. The system of claim 18, wherein the information output by the one or more sensors provide information associated with an ambient environment in which the wearable computing device is being operated including one or more of (i) a geographic location, and (ii) a time.
